(19) United States
(12) Patent Application Publication
(10) Pub. No.: US 2025/0176177 A1
(43) Pub. Date: May 29, 2025

(54) WORD LINE PARTITION IN STACKED MEMORY ARRAYS

(71) Applicant: Micron Technology, Inc., Boise, ID (US)

(72) Inventors: Anna Maria Conti, Milano (IT); Paolo Tessariol, Arcore (IT)

(21) Appl. No.: 18/960,684

(22) Filed: Nov. 26, 2024

Related U.S. Application Data
(60) Provisional application No. 63/604,019, filed on Nov. 29, 2023.

(51) Int. Cl. H10B 43/10; H10B 41/10; H10B 41/27; H10B 41/41; H10B 43/27; H10B 43/40

(52) U.S. Cl. CPC H10B 43/10; H10B 41/10; H10B 41/27; H10B 41/41; H10B 43/27; H10B 43/40

(57) ABSTRACT

An example memory device includes a first active region of a memory array having a pillar lattice structure, a second active region of the array, and a third region electrically separating the first active region from the second active region, wherein the pillar lattice structure is uninterrupted in the third region.

PRIORITY INFORMATION

This application claims the benefit of U.S. Provisional Application No. 63/602,034, filed on Nov. 22, 2023, the contents of which are incorporated herein by reference.

### TECHNICAL FIELD

The present disclosure relates generally to memory arrays and their formation, and more particularly, to word line partitions in stacked memory arrays.

### BACKGROUND

Memory devices are typically provided as internal, semiconductor, integrated circuits in computers or other electronic devices. There are many different types of memory, including random-access memory (RAM), read only memory (ROM), dynamic random access memory (DRAM), synchronous dynamic random access memory (SDRAM), resistive memory (e.g., RRAM), and Flash memory, among others.

Memory devices can be utilized as volatile and non-volatile data storage for a wide range of electronic applications. Volatile memory may require power to maintain its data, whereas non-volatile memory may provide persistent data by retaining stored data when not powered. Flash memory, which is just one type of non-volatile memory, can use a one-transistor memory cells that allow for high memory densities, high reliability, and low power consumption. Non-volatile memory may be used in, for example, personal computers, portable memory sticks, solid state drives (SSDs), digital cameras, cellular telephones, portable music players such as MP3 players, movie players, and other electronic devices. Memory cells can be arranged into arrays, with the arrays being used in memory devices.

Memory devices can have arrays of memory cells. Memory arrays can include groups of memory cells, such as blocks, sub-blocks, strings, etc. In some examples, a memory array can be a stacked memory array that can be referred to as a three-dimensional (3D) memory array. The memory cells at a common location (e.g., at a common vertical level) in a stacked memory array, for example, may form a tier of memory cells. The memory cells in each tier can be commonly coupled to a common access line, such as a word line. In some examples, a group of memory cells can include memory cells from different tiers coupled in series to form a string of series coupled memory cells (e.g., a NAND string) between a select transistor coupled to a source and a select transistor coupled to a data line, such as a bit line.

In some examples, the formation of stacked memory arrays can include a replacement gate process. After semiconductor structures (e.g., semiconductor pillars) are formed through a stack of alternating dielectrics, a replacement gate process can be used to remove dielectrics from the stack at levels at which memory cells are to be formed adjacent to the semiconductor structures and to form conductive access lines (e.g., metal access lines) in place of the removed dielectrics. In various examples, an opening (e.g., a slot or a slit) can be formed through the stack to provide access to the various levels in the stack in order to remove selected dielectric material layers (e.g., via an etchant) and replace them with conductive material (e.g., a metal) levels, which can serve as the access lines.

### BRIEF DESCRIPTION OF THE DRAWINGS

FIG. 1 is a top view of a stacked memory array with split word lines, according to the background art.

FIG. 2A is a top view of a processing stage associated with forming a stacked memory array in accordance with a number of embodiments of the present disclosure.

FIG. 2B is a cross-section viewed along line A-A in FIG. 2A during the processing stage in FIG. 2A in accordance with a number of embodiments of the present disclosure.

FIG. 3A is a top view corresponding to a stage of processing following the stage of processing of FIG. 2 in accordance with a number of embodiments of the present disclosure.

FIG. 3B is a cross-section viewed along line B-B in FIG. 3A during the processing stage in FIG. 3A in accordance with a number of embodiments of the present disclosure.

FIG. 3C is a cross-section viewed along line C-C in FIG. 3A during the processing stage in FIG. 3A in accordance with a number of embodiments of the present disclosure.

FIG. 4A is a top view corresponding to a stage of processing following the stage of processing of FIG. 3 in accordance with a number of embodiments of the present disclosure.

FIG. 4B is a cross-section viewed along line F-F in FIG. 4A during the processing stage in FIG. 4A in accordance with a number of embodiments of the present disclosure.

FIG. 4C is a cross-section viewed along line G-G in FIG. 4A during the processing stage in FIG. 4A in accordance with a number of embodiments of the present disclosure.

FIG. 5A is a top view corresponding to a particular stage of processing associated with forming a stacked memory array in accordance with a number of embodiments of the present disclosure.

FIG. 5B is a cross-section viewed along line H-H in FIG. 5A during the processing stage in FIG. 5A in accordance with a number of embodiments of the present disclosure.

FIG. 5C is a cross-section viewed along line I-I in FIG. 5A in accordance with a number of embodiments of the present disclosure.

FIG. 6A is a top view corresponding to a stage of processing following the stage of processing of FIG. 5 in accordance with a number of embodiments of the present disclosure.

FIG. 6B is a cross-section viewed along line N-N in FIG. 6A during the processing stage in FIG. 6A in accordance with a number of embodiments of the present disclosure.

FIG. 6C is a cross-section viewed along line O-O in FIG. 6A during the processing stage in FIG. 6A in accordance with a number of embodiments of the present disclosure.

FIG. 7A is a top view corresponding to a stage of processing associated with forming a stacked memory array in accordance with a number of embodiments of the present disclosure.

FIG. 7B is a cross-section viewed along line P-P in FIG. 7A during the processing stage in FIG. 7A in accordance with a number of embodiments of the present disclosure.

FIG. 7C is a cross-section viewed along line Q-Q in FIG. 7A during the processing stage in FIG. 7A in accordance with a number of embodiments of the present disclosure.

FIG. 8A is a top view corresponding to a stage of processing following the stage of processing of FIG. 7 in accordance with a number of embodiments of the present disclosure.

FIG. 8B is a cross-section viewed along line V-V in FIG. 8A during the processing stage in FIG. 8A in accordance with a number of embodiments of the present disclosure.

FIG. 8C is a cross-section viewed along line W-W in FIG. 8A during the processing stage in FIG. 8A in accordance with a number of embodiments of the present disclosure.

FIG. 9 illustrates a stacked memory array, in accordance a number of embodiments of the present disclosure.

FIG. 10 is a block diagram of an apparatus in accordance a number of embodiments of the present disclosure.

### DETAILED DESCRIPTION

Word line partitions in stacked memory arrays and their formation are disclosed herein. Some memory arrays may include architectures in which word lines are split into two sections. For example, some memory arrays are sufficiently wide such that splitting their relatively long word lines may be done to preserve RC and random read performances. In many cases, the two sections are equal or substantially equal in size. Two string drivers, each serving a half page section (e.g., 8 KB), can be placed in the center of the plane or at the edges of the plane. In the latter case, the continuity word line electrode is cut in the center of the plane with minimal loss of space and minimal perturbation of symmetry.

Previous approaches to half plane word line splitting may involve forming a gap in the pillar structure to electrically separate the two resulting half word lines. Such approaches suffer from increased losses in word line length as the half plane interruption is undesirably long. In some approaches, for instance, the interruption may be on the order of 20 microns. It is to be understood that the longer the interruption, the greater the reduction in the number of memory cells available to store data.

Embodiments of the present disclosure can electrically separate two half word lines by forming a dielectric extension between two half word lines and without interrupting the pillar structure of the array. As a result, half plane interruption in accordance with embodiments of the present disclosure is reduced compared with previous approaches. In some embodiments, half plane interruption is less than half of the interruption seen in previous approaches. For example, half plane interruption may be on the order of 8 microns. The two resulting half word lines may be referred to herein as a “first active region” and a “second active region,” and the portion of the array between them that is associated with the dielectric extension may be referred to herein as a “partition wall” and/or a “third region.” The dielectric extension can be formed through a stack of alternating first and second dielectrics. For example, the first dielectrics can be at levels in the stack at which memory cells are to be formed adjacent to the semiconductor structures.

The dielectric extension can extend from between groups of the semiconductor structures in the first active region, through the third region, and to the second active region. The dielectric extension can couple the alternating dielectrics in both the first and second active regions to the alternating dielectrics in the third region.

An opening can be formed between groups of semiconductor structures while a dielectric extension couples the alternating dielectrics in the first and second active regions to the alternating dielectrics in the third region. For example, the opening can provide access to the first dielectrics for their removal (e.g., as part of a replacement gate process). The coupling can restrict the movement of the semiconductor structures that can occur while the opening is formed. For example, excessive movement of the semiconductor structures can make it difficult to align data line contacts with the semiconductor structures during subsequent processing.

The first dielectrics in the first and second active regions can be removed while the dielectric extension couples the second dielectrics in the first and second active regions to the alternating dielectrics in the third region. The coupling acts to restrict the movement of the semiconductor structures that can occur while the first dielectrics are removed. In subsequent processing, metal can be formed by supplying the metal through the opening, in spaces corresponding to the first dielectrics to form access lines while the dielectric extension couples the second dielectrics in the first and second active regions to the alternating dielectrics in the third region. The coupling acts to restrict the movement of the semiconductor structures that can occur while the metal is formed.

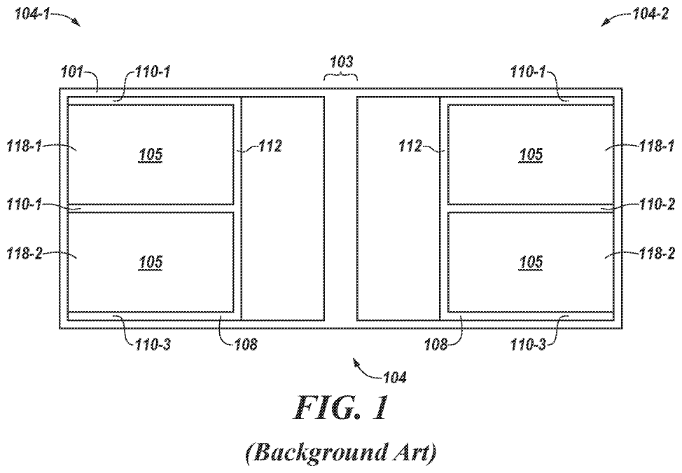

FIG. 1 is a top view of a stacked memory array with split word lines, according to the background art. The array shown in FIG. 1 includes a full plane (e.g., 16 KB) that has been split into two half planes, a first half plane 104-1 and a second half plane 104-2. As shown in FIG. 1, previous approaches to half plane word line splitting may involve forming a gap 103 in the pillar structure to electrically separate the two resulting half word lines. Such approaches suffer from increased losses in word line length as the half plane interruption 106 is undesirably long. In some approaches, for instance, the interruption 106 may be on the order of 20 microns.

In FIG. 1, a stack 101 of alternating dielectrics, such as nitride alternating with oxide, is shown. Semiconductor structures can be included in groups 118-1 and 118-2. In some examples, memory cells can be partially formed adjacent to semiconductor structures 105, such at levels of stack 101 having the nitride.

An opening 108, comprising segments 110-1, 110-2, 110-3, and 112, is formed through stack 101. For example, a removal material selective to nitride can be supplied through opening 108 to remove the nitride while leaving the oxide. In some examples, the partially formed memory cells can be completed by accessing the memory cells through opening 108. Metal, such as tungsten, can be supplied though opening 108 to form access lines that can be coupled to the memory cells. In some examples, formation of opening 108, removal of the nitride, completing the memory cells, and forming the access lines can be formed as part of a replacement gate process.

A dielectric can be formed in opening 108 to electrically isolate the access lines corresponding to group 118-1 from access lines corresponding to group 118-2. The segment 112 of opening 108 is transverse to segments 110-1 to 110-3. For example, segments 110-1 to 110-3 and 112 form respective “T-intersections.” In some examples, opening 108 can be formed during a single process step (e.g., during a single etch) that can form the segments 110-1 to 110-3 and 112 concurrently. However, as an example, the “T-intersections” can be formed by performing a first etch through the stack 101 to form segments 110-1 to 110-3 and a second etch through the stack 101 to form segment 112.

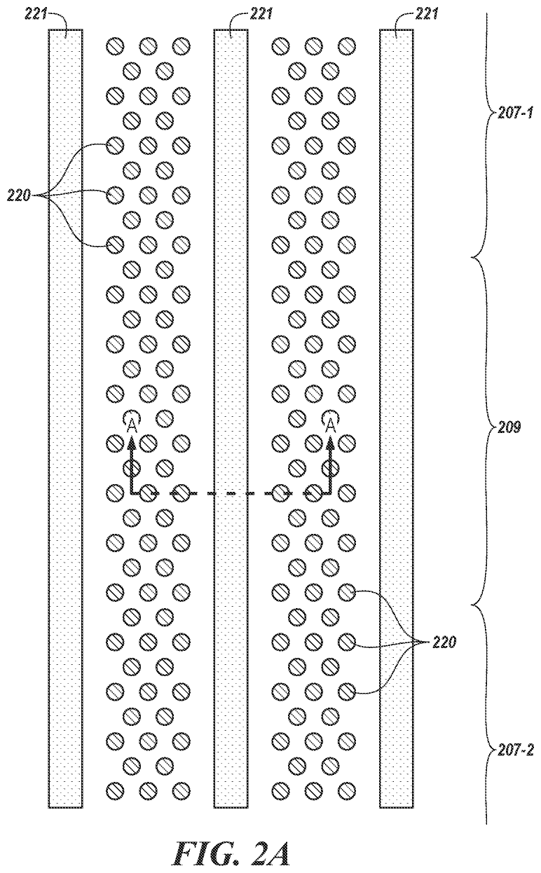

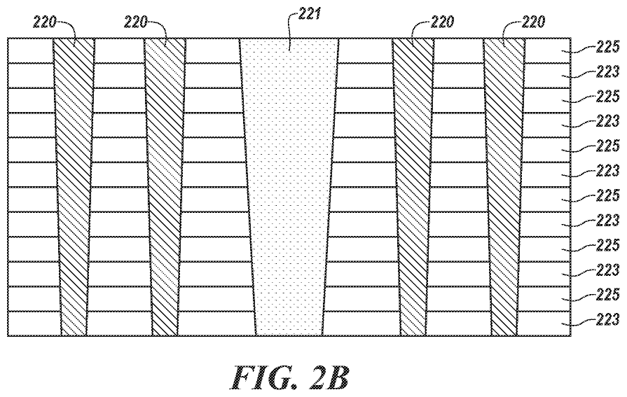

FIGS. 2A to 2B are various views corresponding to particular stages of processing associated with forming a stacked memory array in accordance with a number of embodiments of the present disclosure. FIG. 2A is a top view of a processing stage associated with forming a stacked memory array in accordance with a number of embodiments of the present disclosure. FIG. 2B is a cross-section viewed along line A-A in FIG. 2A during the processing stage in FIG. 2A in accordance with a number of embodiments of the present disclosure. FIG. 2A and 2B may be cumulatively referred to herein as “FIG. 2.” As shown in FIG. 2, pillars 220 can be formed in three regions: a first region 207-1, a second region 207-2, and a third region 209. A dielectric material 221 can be formed in openings of the stack.

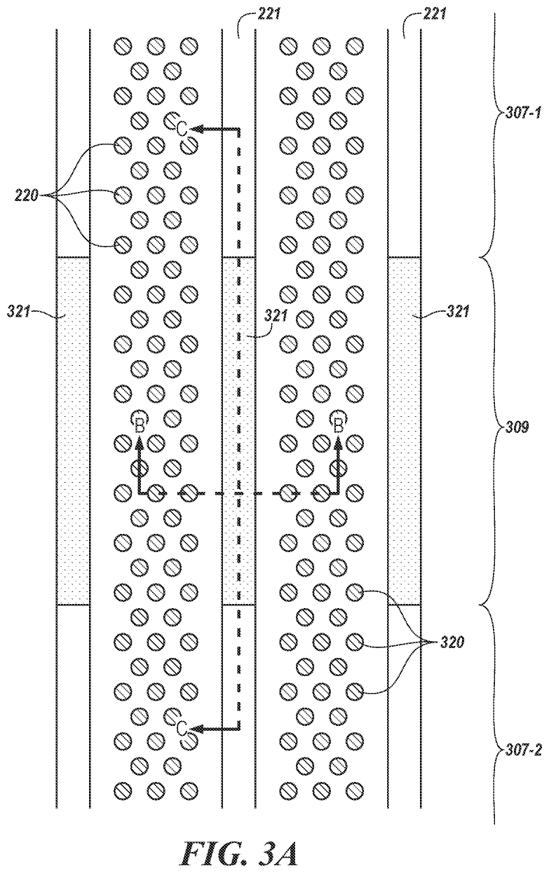

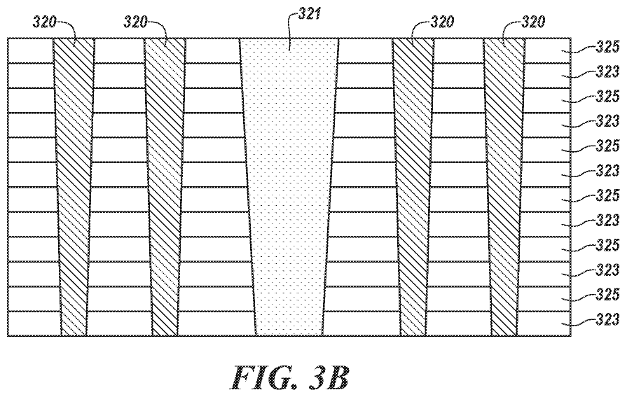

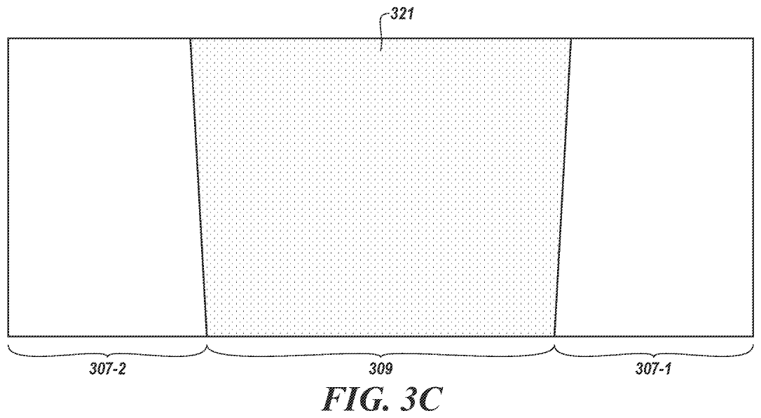

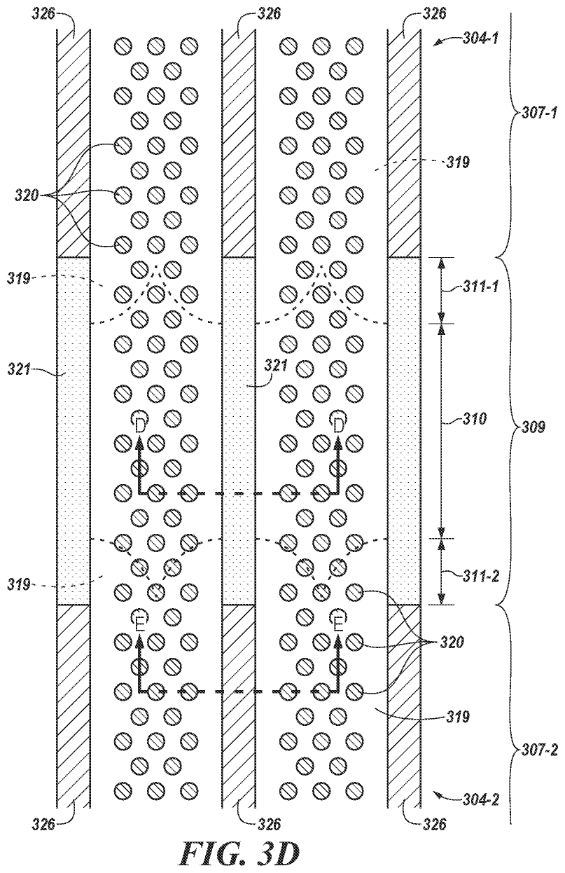

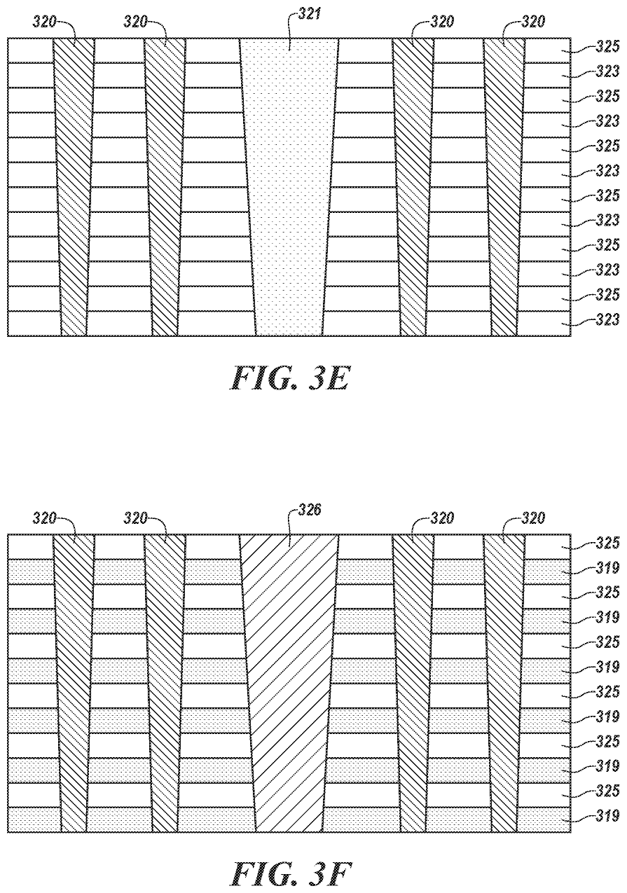

FIGS. 3A to 3C are various views corresponding to particular stages of processing associated with forming a stacked memory array in accordance with a number of embodiments of the present disclosure. FIG. 3A is a top view corresponding to a stage of processing following the stage of processing of FIG. 2 in accordance with a number of embodiments of the present disclosure. FIG. 3B is a cross-section viewed along line B-B in FIG. 3A during the processing stage in FIG. 3A in accordance with a number of embodiments of the present disclosure. FIG. 3C is a cross-section viewed along line C-C in FIG. 3A during the processing stage in FIG. 3A in accordance with a number of embodiments of the present disclosure. FIGS. 3A, 3B, and 3C may be cumulatively referred to herein as “FIG. 3.”

A mask can be formed over a portion of the stack. For example, a mask can be formed over the region 309 to cover a portion of the dielectric 321 in region 309. Portions of the dielectric 321 are removed, as shown FIG. 3A. For example, the dielectric 321 formed in the region 307-1 and the region 307-2 are removed, leaving the dielectric 321 in the region 309. In some examples, the portions of the dielectric 321 that are uncovered by the mask are removed, such as by a wet etch or by a reactive ion etch (RIE), leaving the portions of the dielectric 321 covered by the mask.

FIGS. 3D to 3F are various views corresponding to particular stages of processing associated with forming a stacked memory array in accordance with a number of embodiments of the present disclosure. FIG. 3D is a top view corresponding to a stage of processing following the stage of processing of FIG. 3C in accordance with a number of embodiments of the present disclosure. Metal 319 can be supplied through segments (discussed further below) to form the metal in the spaces. For example, the metal 319 can form access lines that can include control gates of the memory cells and control lines that can include gates of the select transistors. For example, the metal 319 can be formed in the spaces as part of a replacement gate process.

In some examples, after the formation of the metal 319, the dielectric structures can pass through a stack of the dielectrics not removed by the removal material alternating with the metal. FIG. 3E is a top view corresponding to a stage of processing following the stage of processing of FIG. 3D in accordance with a number of embodiments of the present disclosure. As shown in FIG. 3D, after the formation of the metal 319, a dielectric 326 can be formed in the first region and the second region.

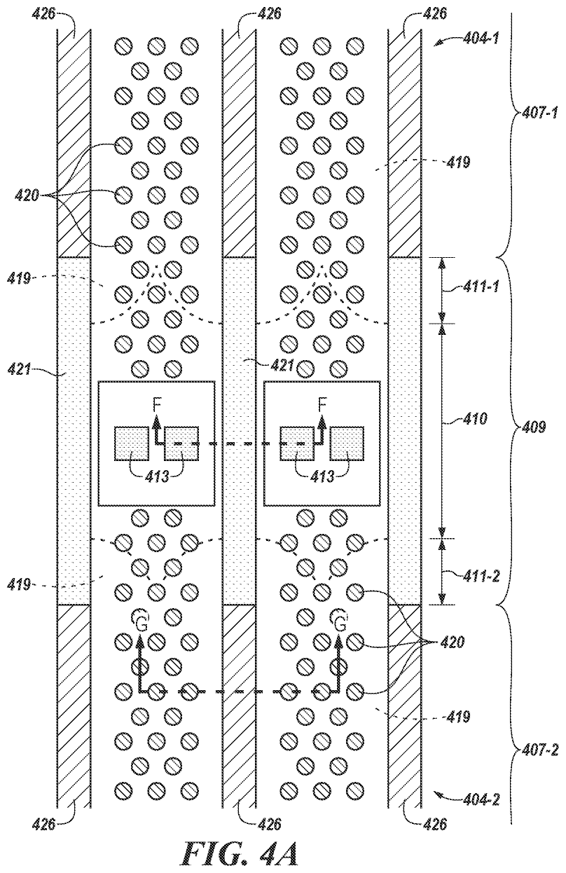

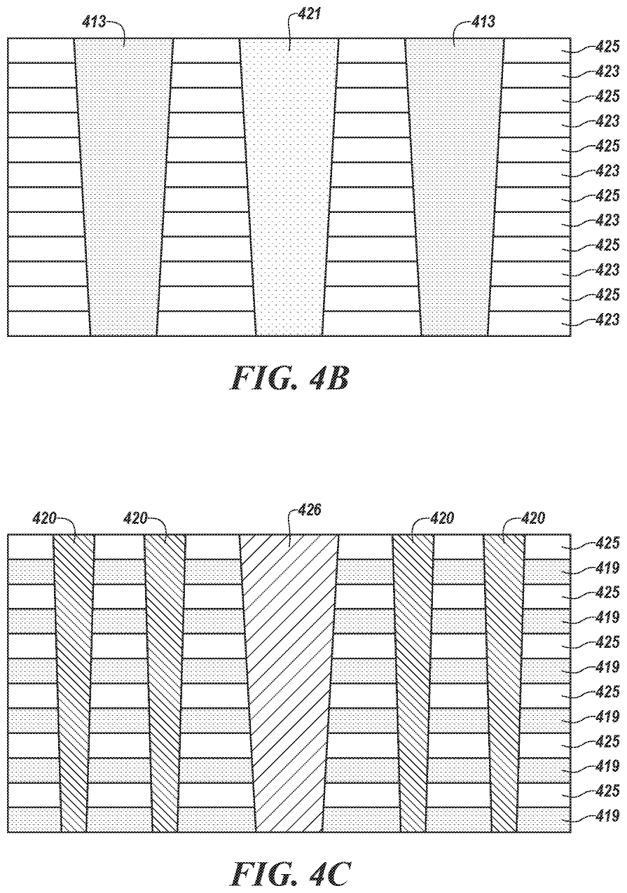

FIG. 4A is a top view corresponding to a stage of processing following the stage of processing of FIG. 3 in accordance with a number of embodiments of the present disclosure. FIG. 4B is a cross-section viewed along line F-F in FIG. 4A during the processing stage in FIG. 4A in accordance with a number of embodiments of the present disclosure. FIG. 4C is a cross-section viewed along line G-G in FIG. 4A during the processing stage in FIG. 4A in accordance with a number of embodiments of the present disclosure. FIGS. 4A, 4B, and 4C may be cumulatively referred to herein as “FIG. 4.”

The example array illustrated in FIG. 4 includes a plurality of points of metal entry 413 in the third region 409. Depending on the number of points of metal entry, the width of the guard band 410 can be increased with respect to the array illustrated in FIG. 2, for instance.

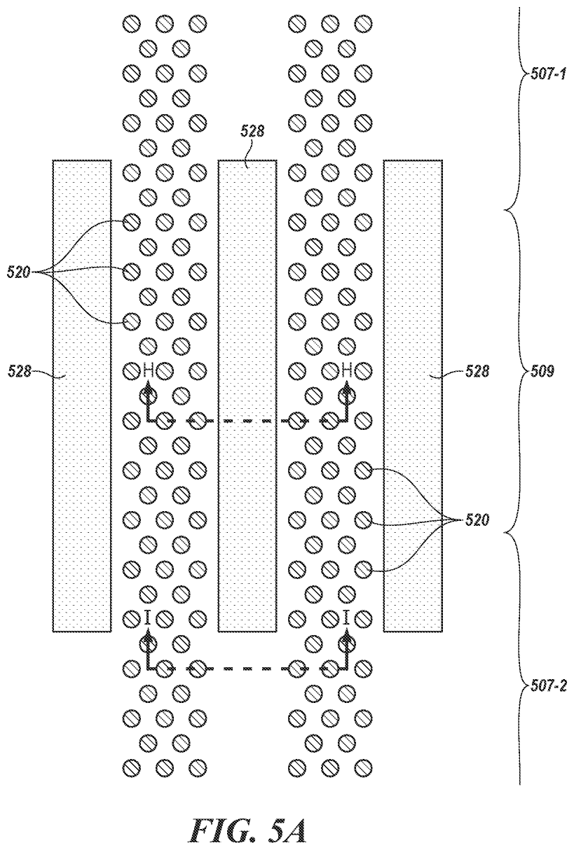

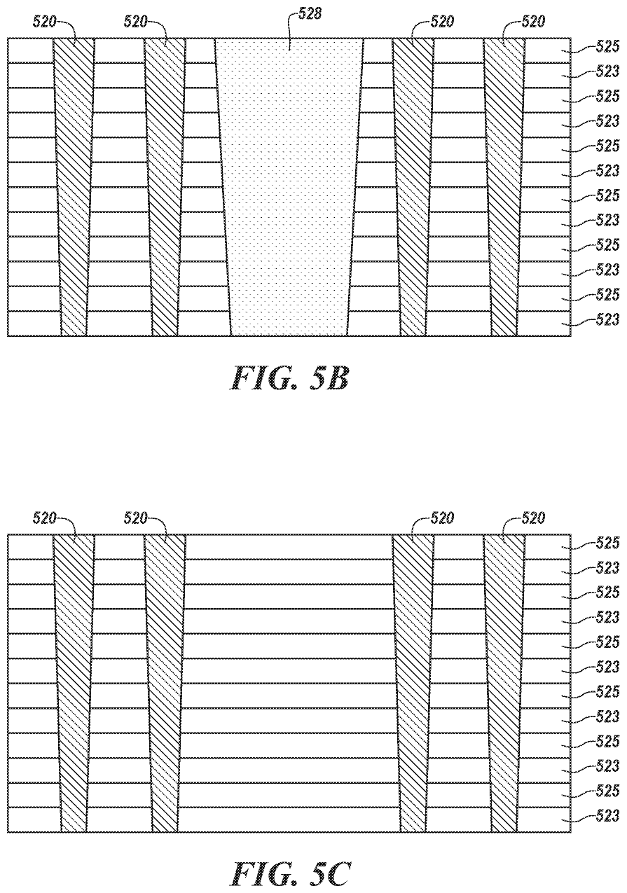

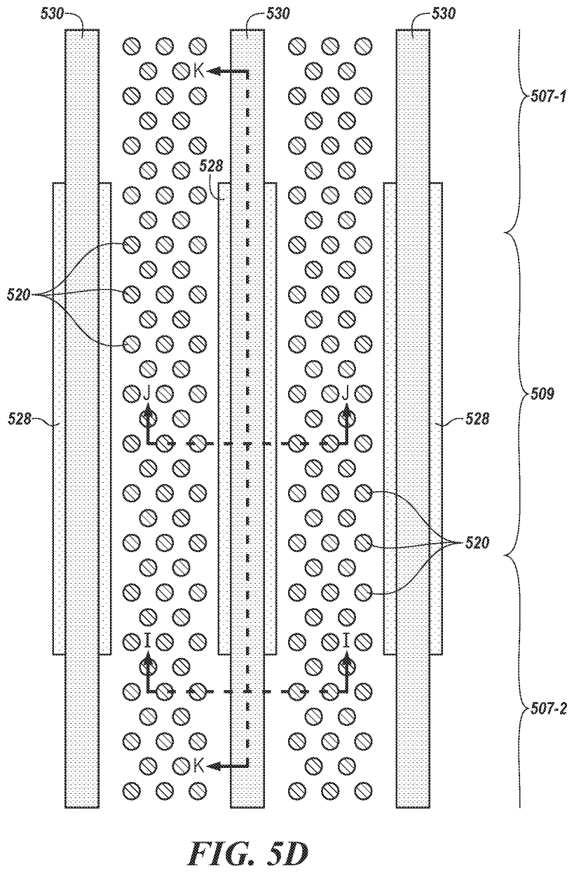

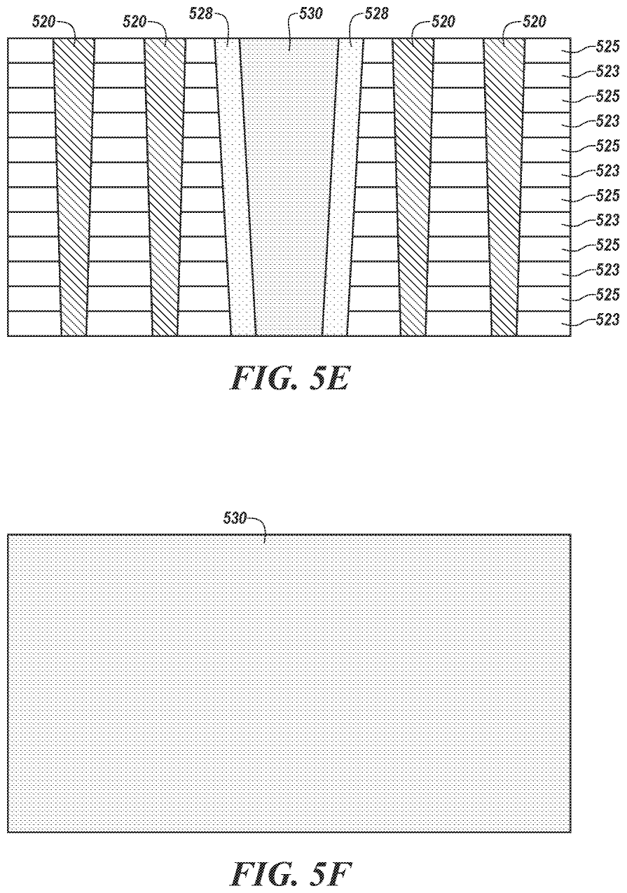

FIG. 5A is a top view corresponding to a particular stage of processing associated with forming a stacked memory array in accordance with a number of embodiments of the present disclosure. In some examples, the array can be a three-dimensional NAND memory array. FIG. 5B is a cross-section viewed along line H-H in FIG. 5A during the processing stage in FIG. 5A in accordance with a number of embodiments of the present disclosure. FIG. 5C is a cross-section viewed along line I-I in FIG. 5A in accordance with a number of embodiments of the present disclosure. FIGS. 5A-5C can correspond to a processing stage that can occur after a number of processing stages have occurred. In some examples, a processing stage can include a number of steps that can have a number of sub-steps.

As shown in FIG. 5, a group of semiconductor structures 520 passes through a region of a stack of alternating dielectrics 523 and 525 formed on (e.g., over) a semiconductor. Semiconductor structures 520 and semiconductor can be polysilicon, silicon conductively doped to have a p-type conductivity (e.g., single crystal p-silicon), or the like. Dielectrics 525 can be oxide, and dielectrics 523 can be nitride. For example, dielectrics 523 can be sacrificial dielectrics that can be removed during a subsequent processing stage.

In the processing stage corresponding to FIGS. 5A-5C, openings are formed through stack. For example, a mask, such as imaging resist, is formed over the uppermost dielectric 525 and is patterned to define regions of stack for removal. The regions defined for removal are subsequently removed (e.g., by etching) to from the openings.

The openings extend from region 509 into the region 507-1 and the region 507-2. During the processing stage of FIGS. 5A-5C, a dielectric extension 528 that can be oxide is formed in the openings. Note that the dielectric extension 528 can couple the alternating dielectrics 523 and 525 to the alternating dielectrics 525 and 523, as shown in FIG. 5B.

FIG. 5D is a top view corresponding to a stage of processing following the stage of processing of FIGS. 5A-5C in accordance with a number of embodiments of the present disclosure. FIG. 5E is a cross-section viewed along line J-J in FIG. 5D during a processing step of the processing stage in FIG. 5D in accordance with a number of embodiments of the present disclosure. FIG. 5F is a cross-section viewed along line K-K in FIG. 5D during the processing step of the processing stage in FIG. 5D in accordance with a number of embodiments of the present disclosure.

During the processing step of FIGS. 5D-5F, openings 530 are formed through the stack and through portions of the dielectric extensions 528, stopping at an upper surface of or in the semiconductor. For example, openings 530 through the dielectric extensions 528 can be performed as part of a replacement gate process. Dielectric extensions 528 and the corresponding openings 530 can overlap in region 509 and portions of regions 507-1 and 507-2. Openings 530 can provide access to alternating dielectrics 523 and 525.

The openings 530 pass through a central portion of the dielectric extension 528 where the opening 530 and the dielectric extension 528 overlap. For example, where any of the openings 530 and the dielectric extensions 528 overlap, the dielectric extension 528 can line the opening 530, as shown in FIG. 5E. For example, as shown in FIG. 5E, a portion of the dielectric extension 528 is between the opening 530 and the alternating dielectrics 523 and 525.

Note that dielectric extensions 528 couple the alternating dielectrics 523 and 525 in region 509 to the alternating dielectrics 525 and 523 while openings 530 are formed. This coupling restricts movement of the semiconductor structures that could occur while openings 530 are formed.

FIG. 5G is a top view corresponding to a stage of processing following the stage of processing of FIGS. 5D-5F in accordance with a number of embodiments of the present disclosure. FIG. 5H is a cross-section viewed along line L-L in FIG. 5G during a processing step of the processing stage in FIG. 5G in accordance with a number of embodiments of the present disclosure. FIG. 5I is a cross-section viewed along line M-M in FIG. 5G during the processing step of the processing stage in FIG. 5G in accordance with a number of embodiments of the present disclosure.

Openings 530 can provide access to dielectrics 523 for the removal of dielectrics 523. For example, dielectrics 523 can be removed as part of a replacement gate process. A removal material, such as a wet etchant, can be supplied through openings 530 to remove dielectrics 523 to form a stack of dielectrics 525 alternating with spaces. Note that the uppermost and lowermost spaces expose the gate dielectrics and the spaces between the uppermost and lowermost spaces expose the blocking dielectrics.

Dielectric extensions 528 couple the alternating dielectrics 523 and 525 to the alternating dielectrics 525 and 523 while dielectrics 523 are removed. This coupling restricts movement of the semiconductor structures that could occur while dielectrics 523 are removed.

The removal material can flow into regions 507-1 and 507-2 from the openings 530. However, the removal material may not flow into the region 509 (e.g., the portions of openings 530 that are overlapped by dielectric extensions 528). The distance by which the dielectric extensions 528 extend into the regions 507-1 and 507-2 can be selected to limit the penetration of the removal material into the region 509. For example, if the distance is too great the removal material might not completely remove the dielectrics 523 from regions 507-1 and 507-2. If the distance is too little, the removal material might remove too much of the dielectrics 523 from region 509. A metal 519, such as tungsten, can be supplied through openings 530 to form metal 519 in the spaces. For example, metal 519 can be formed in the spaces as part of a replacement gate process. As shown in FIG. 3D, after the formation of the metal 319, a dielectric 526 can be formed in the openings 530.

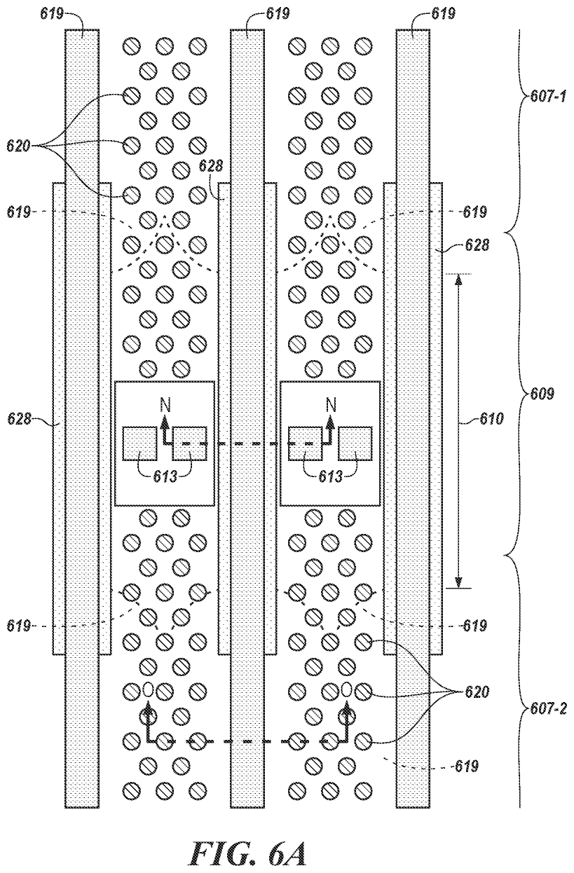

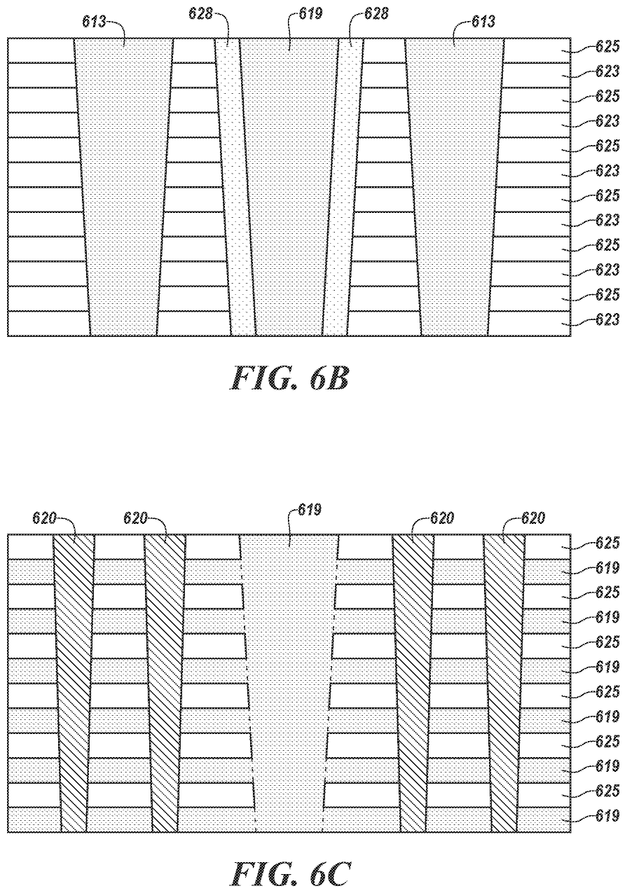

FIGS. 6A to 6C are various views corresponding to particular stages of processing associated with forming a stacked memory array in accordance with a number of embodiments of the present disclosure. FIG. 6A is a top view corresponding to a stage of processing following the stage of processing of FIG. 5 in accordance with a number of embodiments of the present disclosure. FIG. 6B is a cross-section viewed along line N-N in FIG. 6A during the processing stage in FIG. 6A in accordance with a number of embodiments of the present disclosure. FIG. 6C is a cross-section viewed along line O-O in FIG. 6A during the processing stage in FIG. 6A in accordance with a number of embodiments of the present disclosure. FIGS. 6A, 6B, and 6C may be cumulatively referred to herein as “FIG. 6.”

The example array illustrated in FIG. 6 includes a plurality of points of metal entry 613 in the third region 609. Depending on the number of points of metal entry, the width of the guard band 610 can be increased with respect to the array illustrated in FIG. 2, for instance.

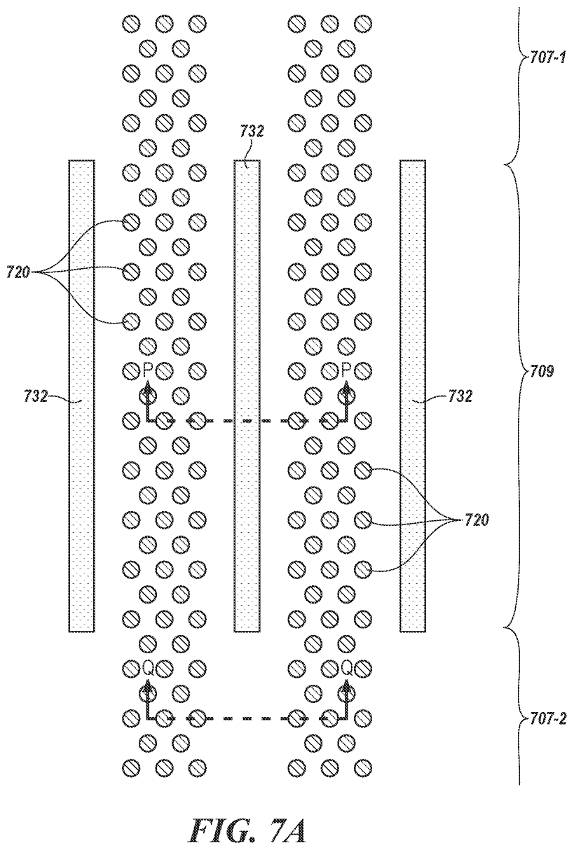

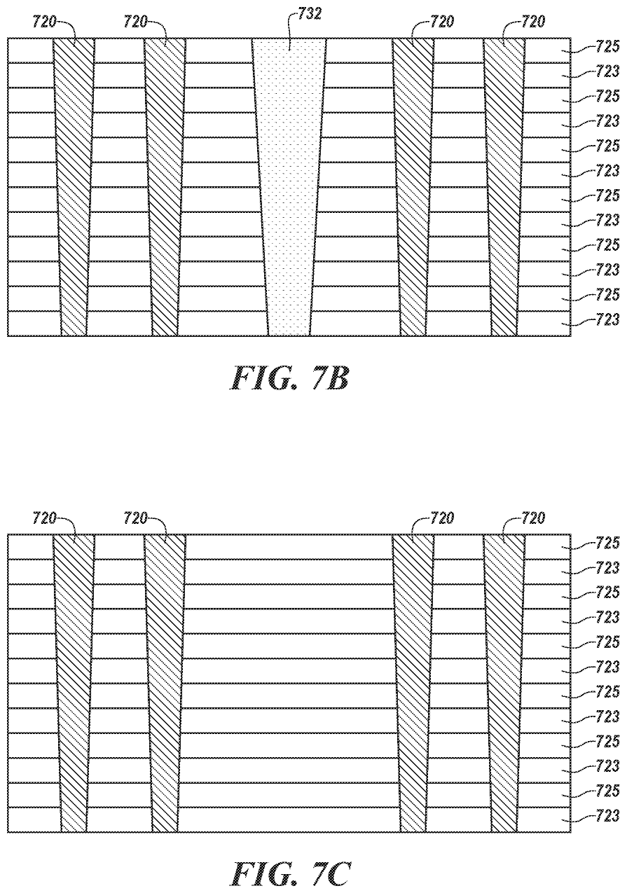

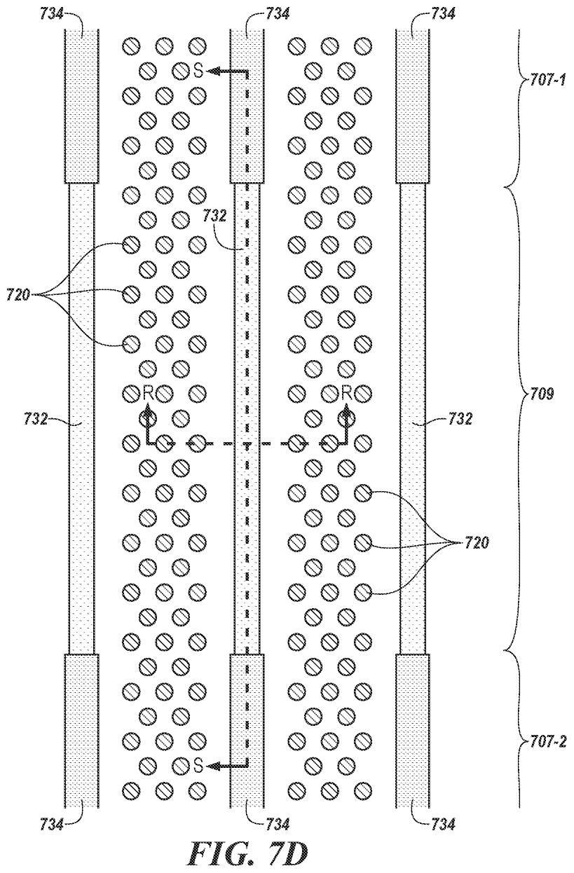

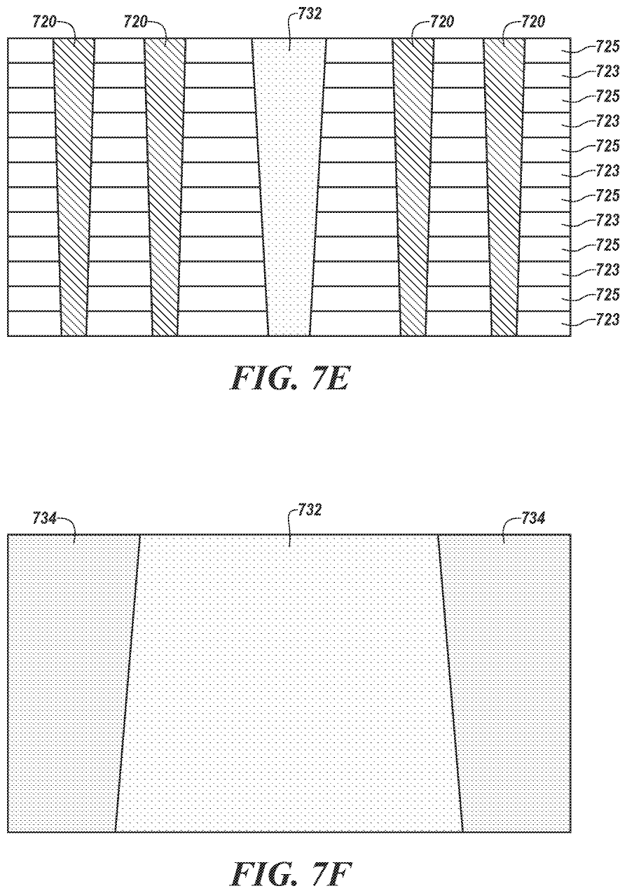

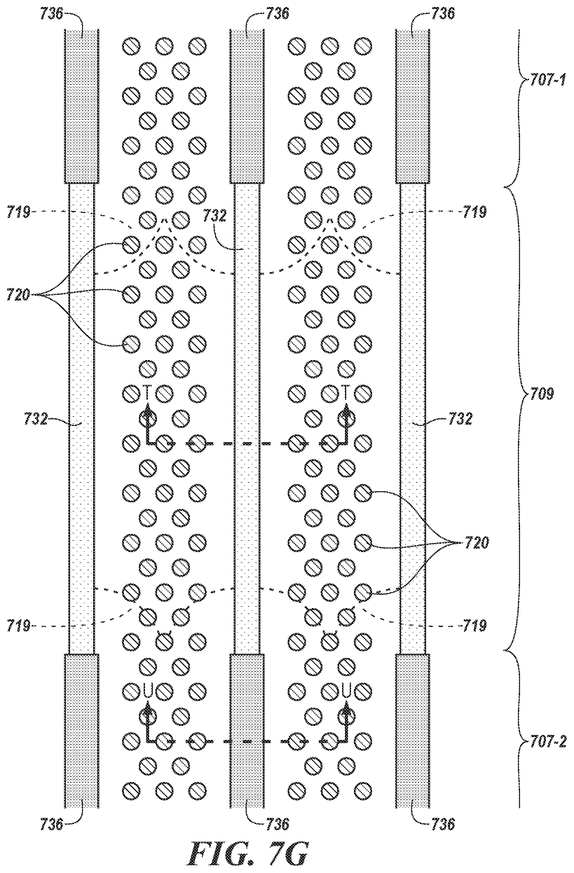

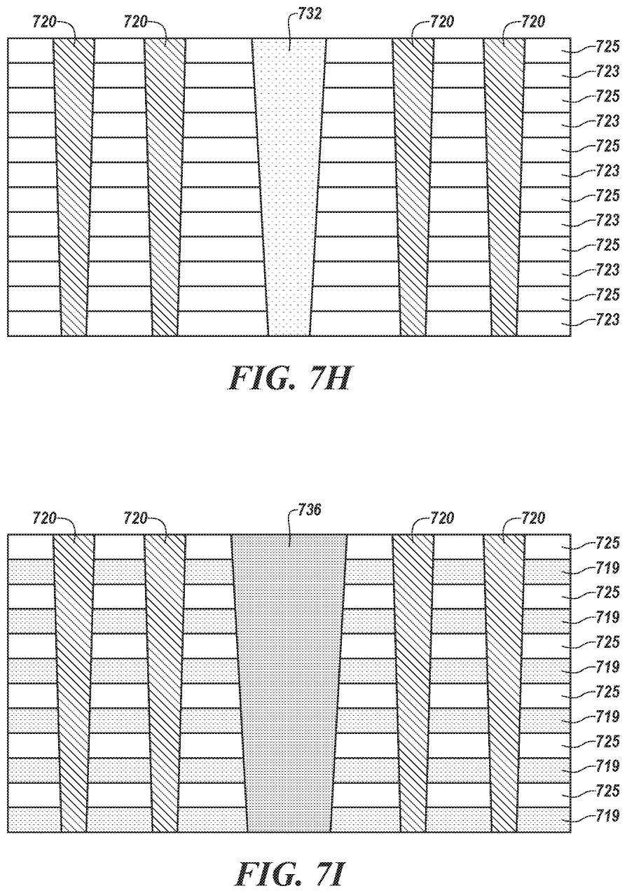

FIGS. 7A to 7I are various views corresponding to particular stages of processing associated with forming a stacked memory array in accordance with a number of embodiments of the present disclosure. FIG. 7A is a top view corresponding to a stage of processing associated with forming a stacked memory array in accordance with a number of embodiments of the present disclosure. FIG. 7B is a cross-section viewed along line P-P in FIG. 7A during the processing stage in FIG. 7A in accordance with a number of embodiments of the present disclosure. FIG. 7C is a cross-section viewed along line Q-Q in FIG. 7A during the processing stage in FIG. 7A in accordance with a number of embodiments of the present disclosure. FIGS. 7A, 7B, 7C, 7D, 7E, 7F, 7G, 7H, 7I may be cumulatively referred to herein as “FIG. 7.”

In the processing stage corresponding to FIGS. 7A-7C, openings are formed through the stack. For example, a mask, such as imaging resist, is formed over the uppermost dielectric 725 and is patterned to define regions of stack for removal. The regions defined for removal are subsequently removed (e.g., by etching) to from the openings.

The openings extend from region 709 into the region 707-1 and the region 707-2. During the processing stage of FIGS. 7A-7C, a dielectric extension 732 that can be oxide is formed in the openings. Note that the dielectric extension 732 can couple the alternating dielectrics 523 and 525 to the alternating dielectrics 525 and 523, as shown in FIG. 7B.

FIGS. 7D to 7F are various views corresponding to particular stages of processing associated with forming a stacked memory array in accordance with a number of embodiments of the present disclosure. FIG. 7D is a top view corresponding to a stage of processing following the stage corresponding to FIGS. 7A-7C in accordance with a number of embodiments of the present disclosure. FIG. 7E is a cross-section viewed along line R-R in FIG. 7D during the processing stage in FIG. 7D in accordance with a number of embodiments of the present disclosure. FIG. 7F is a cross-section viewed along line S-S in FIG. 7D during the processing stage in FIG. 7D in accordance with a number of embodiments of the present disclosure.

In the processing stage corresponding to FIGS. 7D-7F, openings 734 are formed through the stack and abutting portions of the dielectric extensions 732, stopping at an upper surface of or in the semiconductor. For example, openings 734 can be performed as part of a replacement gate process. Dielectric extensions 732 and the openings 734 can abut in regions 707-1 and 707-2. Openings 734 can provide access to alternating dielectrics 723 and 725.

FIGS. 7G to 7I are various views corresponding to particular stages of processing associated with forming a stacked memory array in accordance with a number of embodiments of the present disclosure. FIG. 7G is a top view corresponding to a stage of processing following the stage corresponding to FIGS. 7D-7F in accordance with a number of embodiments of the present disclosure. FIG. 7H is a cross-section viewed along line T-T in FIG. 7G during the processing stage in FIG. 7G in accordance with a number of embodiments of the present disclosure. FIG. 7I is a cross-section viewed along line U-U in FIG. 7G during the processing stage in FIG. 7G in accordance with a number of embodiments of the present disclosure.

As shown in FIGS. 7G to 7I, a metal 719, such as tungsten, can be supplied through openings 734 to form metal 719 in the spaces. For example, metal 719 can be formed in the spaces as part of a replacement gate process. As shown in FIG. 3D, after the formation of the metal 319, a dielectric 736 can be formed in the openings 734.

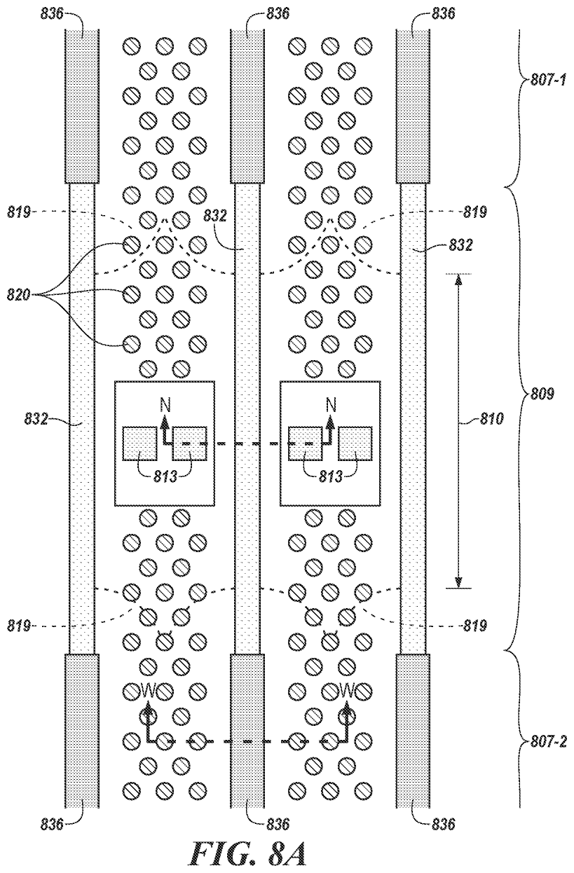

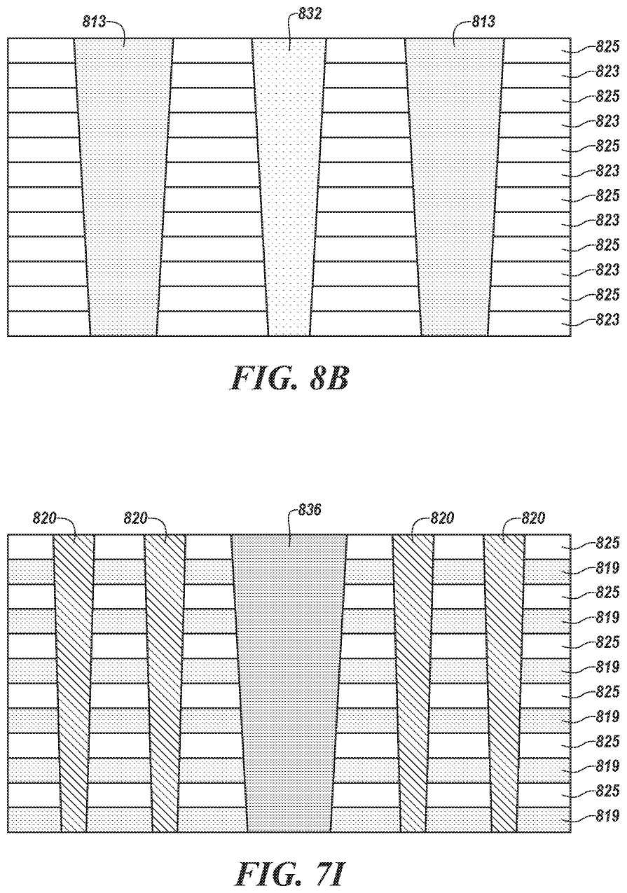

FIG. 8A is a top view corresponding to a stage of processing following the stage of processing of FIG. 7 in accordance with a number of embodiments of the present disclosure. FIG. 8B is a cross-section viewed along line V-V in FIG. 8A during the processing stage in FIG. 8A in accordance with a number of embodiments of the present disclosure. FIG. 8C is a cross-section viewed along line W-W in FIG. 8A during the processing stage in FIG. 8A in accordance with a number of embodiments of the present disclosure. FIGS. 8A, 8B, and 8C may be cumulatively referred to herein as “FIG. 8.”

The example array illustrated in FIG. 8 includes a plurality of points of metal entry 813 in the third region 809. Depending on the number of points of metal entry, the width of the guard band 810 can be increased with respect to the array illustrated in FIG. 2, for instance.

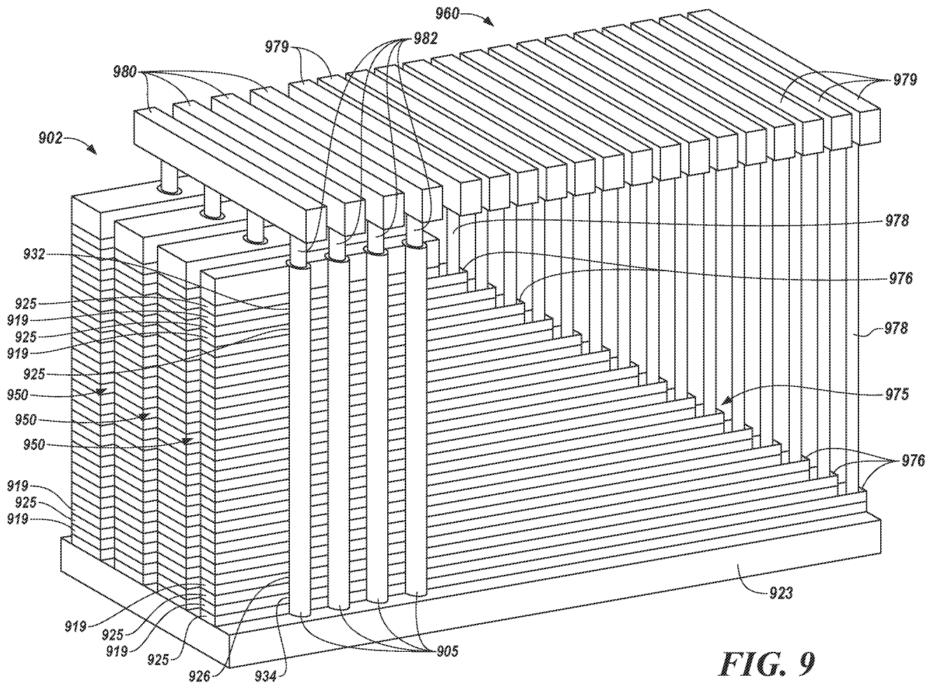

FIG. 9 illustrates a stacked memory array 960, in accordance a number of embodiments of the present disclosure. For example, array 960 can include a region 902 (e.g., a memory-cell region). Array 960 includes a stair-step structure 975 adjacent to region 902.

Array 960 can include a stack of dielectrics 925 alternating with levels of metal 919. Semiconductor structures 905 pass through the stack in region 902 and terminate at an upper surface of or in a semiconductor 925. A select transistor 932 can be adjacent to each semiconductor structure 905 at a level corresponding to the uppermost level of metal 919, and a select transistor 934 can be adjacent to each semiconductor structure 905 at a level corresponding to the lowermost level of metal 919. Memory cells 926 can be adjacent to each semiconductor structure 905 at levels corresponding to the levels of metal 919 between the uppermost and lowermost levels of metal 919.

The uppermost and lowermost levels of metal 919 can be control lines that form or are coupled to control gates of select transistors 932 and 934, respectively. The levels of metal 919 between the uppermost and lowermost levels of metal 919 can be access lines that form or are coupled to control gates of memory cells 926.

Stair-step structure 975 includes steps 976 that can each include a respective level of metal 919 over an adjacent dielectric 925. A respective contact 978 is coupled to the level of metal 919 of each respective step 976. Respective contacts 978 can be coupled to activation (e.g., access) circuitry by respective lines 979. Data lines 980 are coupled to semiconductor structures 905 by data line contacts 982.

Openings 950 are formed through the stack. Openings 950 can terminate at dielectric extensions in a manner similar to that previously described herein. For example, dielectric extensions, such as dielectric liners 947, can line segments of openings 950.

The dielectric extensions can provide more compact isolations between adjacent blocks on either side of openings 950 in FIG. 9 compared to previous approaches. For example, some previous approaches may add another stair-step structure opposite to stair-step structure 975 in FIG. 9 to isolate adjacent blocks on either side of openings 950. However, the added stair-step structure can take up additional space compared to the dielectric extensions.

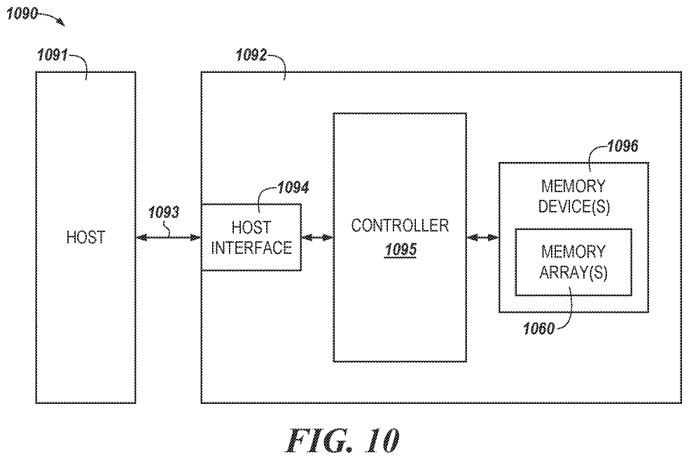

FIG. 10 is a block diagram of an apparatus in accordance a number of embodiments of the present disclosure. For example, the apparatus can be an electronic system, such as a computing system 1090. Computing system 1090 can include a memory system 1092 that can be a solid-state drive (SSD), for instance. Memory system 1092 can include a host interface 1094, a controller 1095, such as a processor and/or other control circuitry, and a number of memory devices 1096, such as NAND flash devices, that provide a storage volume for the memory system 1092. A memory device 1096 can have a number of memory arrays 1060, such as the memory arrays described herein.

Controller 1095 can be coupled to the host interface 1094 and to the number of memory devices 1096 via one or more channels and can be used to transfer data between the memory system 1092 and a host 1091. Host 1091 can be coupled to the host interface 1094 by a communication channel 1093. Host 1091 can be a host system such as a personal laptop computer, a desktop computer, a digital camera, a mobile telephone, or a memory card reader, among various other types of hosts.

The term semiconductor can refer to, for example, a layer of material, a wafer, or a substrate, and includes any base semiconductor structure. “Semiconductor” is to be understood as including silicon-on-sapphire (SOS) technology, silicon-on-insulator (SOI) technology, thin film transistor (TFT) technology, doped and undoped semiconductors, epitaxial layers of a silicon supported by a base semiconductor structure, as well as other semiconductor structures well known to one skilled in the art. Furthermore, when reference is made to a semiconductor in the following description, previous process steps may have been utilized to form regions/junctions in the base semiconductor structure, and the term semiconductor can include the underlying layers containing such regions/junctions.

As used herein, “a” or “an” can refer to one or more of something, and “a number of” something can refer to one or more of such things. For example, a number of memory cells can refer to one or more memory cells. A “plurality” of something intends two or more. As used herein, the term “coupled” may include electrically coupled, directly coupled, and/or directly connected with no intervening elements (e.g., by direct physical contact) or indirectly coupled and/or connected with intervening elements. The term coupled may further include two or more elements that co-operate or interact with each other (e.g., as in a cause and effect relationship). As used herein, multiple acts being performed concurrently refers to acts overlapping, at least in part, over a particular time period.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

1. A memory device, comprising:
a first active region of a memory array, wherein the array comprises a pillar lattice structure;
a second active region of the array; and
a third region electrically separating the first active region from the second active region, wherein the pillar lattice structure is uninterrupted in the third region.

2. The memory device of claim 1, wherein the first active region corresponds to a first half-plane of the memory array and wherein the second active region corresponds to a second half-plane of the memory array.

3. The memory device of claim 1, wherein the first active region and the second active region are substantially a same size.

4. The memory device of claim 1, wherein the first active region includes a first portion of a word line and the second active region includes a second portion of the word line.

5. The memory device of claim 4, wherein the word line comprises memory cells corresponding to a 16 kilobyte page size.

6. The memory device of claim 1, further comprising:
a first set of string drivers at a first end of the array and associated with the first active region; and
a second set of string drivers at a second end of the array and associated with the second active region.

7. The memory device of claim 1, further comprising a plurality of points of metal entry in the third region.

8. The memory device of claim 1, further comprising a plurality of metal contacts in the third region.

9. A method of forming a stacked memory array, comprising:
forming a stack of alternating first and second dielectrics;
forming a dielectric extension through the stack such that:
a first portion of the dielectric extension is in a first region of the stack;
a second portion of the dielectric extension is in a second region of the stack; and
a third portion of the dielectric extension is in a third region of the stack that separates the first region from the second region;
removing the first portion of the dielectric extension, the second portion of the dielectric extension, and first dielectrics from the first region and the second region; and
forming a conductive material in spaces of the first region and the second region formed by removing the first portion of the dielectric extension, the second portion of the dielectric extension, and the first dielectrics.

10. The method of claim 9, wherein forming the conductive material includes forming a metal.

11. The method of claim 9, wherein the metal comprises tungsten.

12. The method of claim 9, wherein the method includes forming a plurality of metal contacts in the third region subsequent to forming the conductive material.

13. The method of claim 9, wherein removing the first dielectrics from the first region and the second region is performed as part of a replacement gate process.

14. The method of claim 9, wherein the method includes:
forming a first lateral memory cell region including first and second groups of memory cells and a first dielectric between the first and second groups; and
forming a second lateral memory cell region including third and fourth groups of memory cells and the first dielectric between the third and fourth groups.

15. The method of claim 9, wherein the first dielectrics comprise oxide.

16. A stacked memory array, comprising:
a medial region comprising a pillar lattice structure;
a first lateral memory cell region comprising the pillar lattice structure; and
a second lateral memory cell region comprising the pillar lattice structure and electrically separated from the first lateral memory cell region by the medial region.

17. The array of claim 16, wherein:
the first lateral memory cell region includes first and second groups of memory cells and a first dielectric between the first and second groups; and
the second lateral memory cell region includes third and fourth groups of memory cells and the first dielectric between the third and fourth groups.

18. The array of claim 17, wherein the first dielectric comprises oxide.

19. The array of claim 16, wherein a width of the medial region is less than 10 microns.

20. The array of claim 16, wherein the pillar lattice structure is uninterrupted across the array.
